(19) United States
(12) Patent Application Publication
(10) Pub. No.: US 2022/0020663 A1
(43) Pub. Date: Jan. 20, 2022

(54) THERMALLY CONDUCTIVE MOLDING, PRODUCTION METHOD FOR THE SAME, STRUCTURE, AND MULTILAYER FILM

(71) Applicant: 3M INNOVATIVE PROPERTIES COMPANY, St. Paul, MN (US)

(72) Inventors: Tomoaki Uchiya, Tokyo (JP); Naoyuki Toriumi, Kanagawa Pref. (JP); Eisuke Yamaguchi, Tokyo (JP); Guanqiao Li, Kanagawa Pref. (JP)

(21) Appl. No.: 17/311,458

(22) PCT Filed: Dec. 9, 2019
(86) PCT No.: PCT/IB2019/060576

§ 371 Date: Jun. 7, 2021

(30) Foreign Application Priority Data
Dec. 13, 2018 (JP) 2018-233497

(51) Int. Cl. H01L 23/373; H05K 7/20; H01L 23/29; H01L 23/42; B29C 39/10; B32B 27/08

(52) U.S. Cl. CPC H01L 23/3737; H05K 7/2039; B32B 27/08; H01L 23/42; B29C 39/10; H01L 23/295

(57) ABSTRACT

The production method for a thermally conductive molding includes: preparing a first film that is disposed on a mold having a three-dimensional shape so as to conform to the three-dimensional shape, and that has a first layer and a second layer that is releasably adhered to the first layer on a surface opposite to the mold of the first layer; disposing a curable composition including a thermally conductive material and a (meth)acrylic monomer on the first film; disposing a second film on the curable composition and sandwiching the curable composition between the first film and the second film; radically polymerizing the (meth)acrylic monomer in the curable composition to form a cured product of the curable composition between the first film and the second film; and releasing the first layer from the second layer to obtain a thermally conductive molding including the second layer, the cured product, and the second film.

### TECHNICAL FIELD

The present invention relates to a thermally conductive molding, a production method for the same, a structure, and a multilayer film.

### BACKGROUND ART

In order to efficiently cool heat generated by heat-generating components mounted on electronic apparatuses (e.g., on-vehicle battery packs), thermally conductive moldings are applied between the heat-generating components and heat-dissipating components such as heat sinks, thereby improving heat dissipation of the heat generating components. Such a thermally conductive molding is produced by, for example, a method including a step of preparing a composition containing a resin base material and a thermally conductive filler, a step of charging the composition into a tray recess of a heat resistant tray having a shape corresponding to a desired shape, and a step of heat curing the composition packed in the tray recess (see Patent Document 1).

### CITATION LIST

Patent Document 1: JP 2016-92227 A

### SUMMARY OF INVENTION

An object of the present invention is to provide a novel production method for producing a thermally conductive molding having excellent thermal conductivity, a thermally conductive molding obtained by the production method, and a structure for producing a thermally conductive molding, and a multilayer film.

### Solution to Problem

One aspect of the present invention relates to a production method for a thermally conductive molding, the production method including: a step of preparing a first film that is disposed on a mold having a three-dimensional shape so as to conform to the three-dimensional shape, that has a shape corresponding to the three-dimensional shape, and that has a first layer and a second layer that is releasably adhered to the first layer on a surface opposite to the mold of the first layer; a step of disposing a curable composition including a thermally conductive material and a (meth)acrylic monomer on the first film; a step of disposing a second film on the curable composition and sandwiching the curable composition between the first film and the second film; a step of radically polymerizing the (meth)acrylic monomer in the curable composition to form a cured product of the curable composition between the first film and the second film; and a step of releasing the first layer from the second layer to obtain a thermally conductive molding including the second layer, the cured product, and the second film. In the production method described above, an oxygen transmissivity of the first film is less than 1000 ml/m²·24 h·atm, and a 50% elongation strength of the first film at 100° C. is 100 N/25 mm or less.

Another aspect of the present invention relates to a structure including: a resin molding having a first surface with a three-dimensional shape and including a thermally conductive material and a (meth)acrylate polymer; and a first film that is disposed on the first surface of the resin molding so as to conform to the three-dimensional shape and that has a second layer and a first layer that is releasably adhered to the second layer on the surface opposite to the resin molding. In the structure described above, an oxygen transmissivity of the first film is less than 1000 ml/m²·24 h·atm, and a 50% elongation strength of the first film at 100° C. is 100 N/25 mm or less.

Another aspect of the present invention relates to a thermally conductive molding formed by releasing the first layer from the second layer of the structure according to the present invention described above and including a second layer and a resin molding.

Another aspect of the present invention relates to a thermally conductive molding including: a resin molding having a first surface with a three-dimensional shape and including a thermally conductive material and a (meth)acrylate polymer; and a film disposed on the first surface of the resin molding so as to conform to the three-dimensional shape.

Another aspect of the present invention relates to a multilayer film having a first layer having an oxygen transmissivity of less than 1000 ml/m²·24 h·atm and a second layer releasably adhered to one side of the first layer. In the multilayer film, the kinetic coefficient of friction of the surface of the second layer on the first layer side is 0.7 or less.

### Advantageous Effects of Invention

According to the present invention, provided are a novel production method for producing a thermally conductive molding having excellent thermal conductivity, a thermally conductive molding obtained by the production method, a structure for producing a thermally conductive molding, and a multilayer film.

### BRIEF DESCRIPTION OF DRAWINGS

FIG. 1 is a perspective view schematically illustrating an embodiment of a thermally conductive molding.

FIG. 2 is a cross-sectional view illustrating an embodiment of a thermally conductive molding.

FIG. 3 is a process cross-sectional view illustrating an embodiment of a production method for a thermally conductive molding.

FIG. 4 is a cross-sectional view illustrating an embodiment of a structure.

FIG. 5 is a diagram illustrating the three-dimensional shape of the mold used in the examples.

### DESCRIPTION OF EMBODIMENTS

Detailed descriptions of the preferable embodiments according to the present invention are given below with reference to the attached drawings as necessary. However, the present invention is not intended to be limited to the embodiments described above.

### Thermally Conductive Molding

The thermally conductive molding according to the present embodiment includes a resin molding having a first surface with a three-dimensional shape; and a film disposed on the first surface of the resin molding so as to conform to the three-dimensional shape. Here, the thermally conductive molding according to the present embodiment can be formed by releasing the first layer (film (A) including the first layer) from the second layer (film (B) including the second layer) of the structure according to the present embodiment described below and can be regarded as including the second layer and a resin molding. That is, the film may be regarded as the second layer (film (B) including the second layer).

The three-dimensional shape may be appropriately set according to the shape of an adherend (e.g., a heat-generating component or a heat-dissipating component) to which the thermally conductive molding is applied. For example, the shape may be any shape conforming to the surface shape of the adherend and may be any shape that facilitates installation at the application site.

The three-dimensional shape is not particularly limited, but for example, at least its portion may be hemispherical, semi-cylindrical, substantially pyramidal (e.g., substantially hexagonal pyramidal). The three-dimensional shape facilitates alignment with the adherend while sliding and thus provides excellent workability. Furthermore, after the alignment, the three-dimensional shape can be deformed by being pressed against the adherend, whereby a certain contact area is ensured.

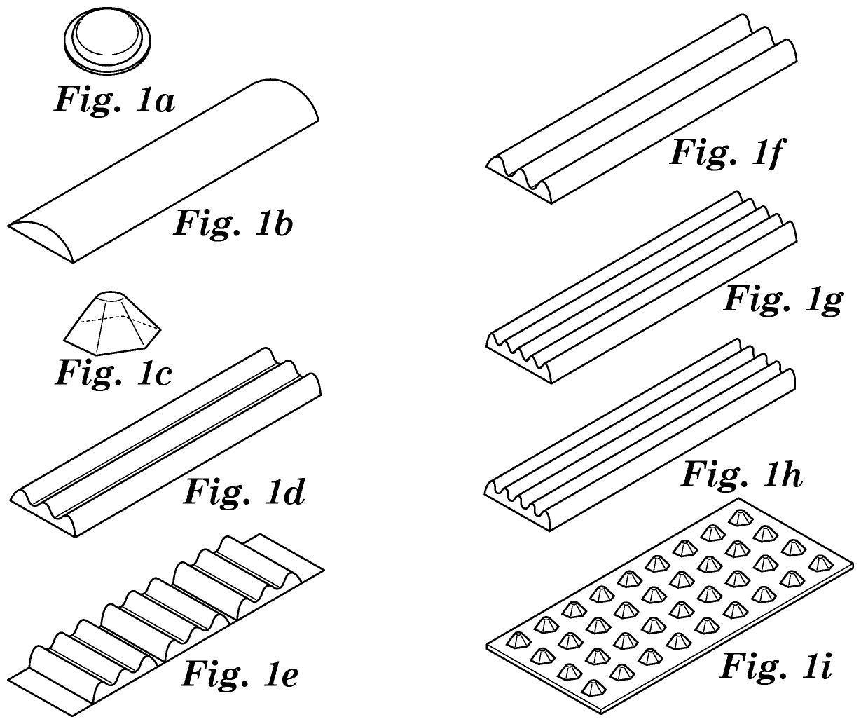

FIG. 1 is a perspective view schematically illustrating an embodiment of a thermally conductive molding. FIGS. 1(a) to 1(i) illustrate specific examples of a thermally conductive molding having a three-dimensional shape portion. As illustrated in FIGS. 1(a) to 1(c), for example, the thermally conductive molding having a three-dimensional shape portion may be, for example, hemispherical, semi-cylindrical, or substantially pyramidal. Furthermore, the size, number, placement location, and the like of the three-dimensional shape part in the thermally conductive molding may be set appropriately in consideration of the shape, size, and the like of the component to which the thermally conductive molding is applied. For example, as illustrated in FIGS. 1(d) to 1(i), a plurality of three-dimensional portions (specifically, two or more, three or more, or five or more three-dimensional portions) may be arranged regularly (e.g., parallel or lattice) in the thermally conductive molding. In addition, a plurality of three-dimensional shapes having different shapes may be present in one thermally conductive molding.

The resin molding includes a thermally conductive material and a (meth)acrylate polymer.

The thermally conductive material is a component that imparts substantial thermal conductivity to the resin molding. The thermally conductive material is not particularly limited but may be, for example, a known thermally conductive filler.

Examples of the thermally conductive material include metal hydrate compounds, metal oxides, metal nitrides, and metal carbides.

Examples of the metal hydrate compound include aluminum hydroxide, magnesium hydroxide, barium hydroxide, calcium hydroxide, dawsonite, hydrotalcite, zinc borate, calcium aluminate, and zirconium oxide hydrate. Examples of the metal oxides include aluminum oxide, magnesium oxide, beryllium oxide, titanium oxide, zirconium oxide, and zinc oxide. Examples of the metal nitride include boron nitride, aluminum nitride, and silicon nitride, and examples of the metal carbide include boron carbide, aluminum carbide, and silicon carbide.

These thermally conductive materials are usually added in the form of the particles. The content (filling amount) of the thermally conductive material can be increased by using a combination of a relatively large particle diameter group having an average particle size of 10 to 100 μm and a relatively small particle diameter group having an average particle size of less than 10 μm. The average particle size refers to the particle size at the integrated value of 50% in the particle size distribution determined by the laser diffraction scattering method.

The thermally conductive material (thermally conductive filler) may be surface treated using a silane coupling agent, a titanate coupling agent, or a surface treatment agent such as a fatty acid. The use of the surface treated thermally conductive material improves the strength (for example, tensile strength) of the thermally conductive molding. Furthermore, the surface treatment markedly decreases the viscosity of the curable composition described below and thus is preferable in the producing process. The thermally conductive material may be surface treated in advance, but the effect of the surface treatment can be obtained by adding a coupling agent or surface treatment agent together with the thermally conductive material in the curable composition described below.

The content of the thermally conductive material in the resin molding is preferably from 55 to 95% by volume and more preferably from 65 to 85% by volume, based on the total amount of the resin molding. When the content of the thermally conductive material is within the range described above, sufficient thermal conductivity can be obtained, embrittlement of the resin molding and difficulty in its production due to excessive content of the thermally conductive material are prevented, and a thermally conductive molding having sufficient strength and flexibility is easily obtained.

The (meth)acrylate polymer is a polymer obtained by polymerizing a monomer component containing a (meth)acrylic monomer. The polymerization may be performed by radical polymerization, as described below. The “(meth)acrylic monomer” refers to acrylic monomers such as acrylic acid and acrylic acid esters, and/or methacrylic monomers such as methacrylic acid and methacrylic acid esters. That is, the (meth)acrylate polymer can also be a polymer obtained by polymerizing a monomer component containing at least one type of monomer selected from the group consisting of acrylic monomers and methacrylic monomers.

The (meth)acrylic monomer is not particularly limited as long as it is a monomer used to form a typical (meth)acrylate polymer. The (meth)acrylic monomer may be used alone or in combination of two or more of them.

The monomer component preferably contains at least a monofunctional (meth)acrylic monomer as the (meth)acrylic monomer. The monofunctional (meth)acrylic monomer is a monomer having one (meth)acryloyl group.

Examples of the monofunctional (meth)acrylic monomer include (meth)acrylic acid, alkyl (meth)acrylate, aryl (meth)acrylate, (meth)acrylamide, epoxy acrylate, and urethane acrylate.

Of these, an alkyl (meth)acrylate having an alkyl group with a carbon number of 12 to 20 is preferable as the monofunctional (meth)acrylic monomer. Here, the alkyl group may be linear, branched, or cyclic.

Additionally, two or more types of alkyl (meth)acrylates having different carbon numbers are preferably used as the monofunctional (meth)acrylic monomers. In this case, by adjusting the content of each alkyl (meth)acrylate, flexibility of the obtained resin molding can be appropriately adjusted depending on the application.

The monomer component may further contain a polyfunctional (meth)acrylic monomer as the (meth)acrylic monomer. Note that the polyfunctional (meth)acrylic monomer is a monomer having two or more (meth)acryloyl groups. When the monomer component contains a polyfunctional (meth)acrylic monomer, the (meth)acrylate polymer has a crosslinked structure, so the strength of the resin molding is improved.

Examples of the polyfunctional (meth)acrylic monomer include: bifunctional (meth)acrylic monomers such as 1,6-hexanediol di (meth)acrylate, 1,4-butanediol di(meth)acrylate, ethylene glycol di(meth)acrylate, diethylene glycol di(meth)acrylate, tetraethylene glycol di(meth)acrylate, tripropylene glycol di(meth)acrylate, neopentyl glycol di(meth)acrylate, poly(butanediol) di(meth)acrylate, 1,3-butylene glycol di(meth)acrylate, triethylene glycol di(meth)acrylate, triisopropylene glycol di(meth)acrylate, polyethylene glycol di(meth)acrylate, and bisphenol A di(meth)acrylate; trifunctional (meth)acrylic monomers such as trimethylolpropane tri(meth)acrylate, pentaerythritol monohydroxytri(meth)acrylate, and trimethylolpropane triethoxytri(meth)acrylate; tetrafunctional (meth)acrylic monomers such as pentaerythritol tetra(meth)acrylate and di-trimethylolpropane tetra(meth) acrylate; and pentafunctional (meth)acrylic monomers such as dipentaerythritol (monohydroxy)penta(meth)acrylate.

The content of the polyfunctional (meth)acrylic monomer in the monomer component is preferably from 0.01 to 5 parts by mass, per 100 parts by mass of the monofunctional (meth)acrylic monomer. When the content is in this range, the strength improving effect of the resin molding due to its crosslinked structure can be sufficiently obtained, a decrease in flexibility due to excessive crosslinking is avoided, and thus a thermally conductive molding having high flexibility is obtained.

The content of the (meth)acrylate polymer in the resin molding is preferably from 0.05 to 30% by mass and more preferably from 0.5 to 15% by mass, based on the total amount of the resin molding.

The resin molding may contain a component other than those described above. For example, the resin molding may contain additives such as antioxidants; tackifiers; plasticizers; flame retardants; flame retardant auxiliaries; anti-settling agents; thickeners; thixotropic agents such as ultrafine silica; surfactants; anti-foaming agents; colorants; antistatic agents; and metal deactivators. These additives may be used alone or in combination of two or more thereof.

In the thermally conductive molding according to the present embodiment, the kinetic coefficient of friction of the surface of the second layer on the opposite side to the resin molding is preferably 0.7 or less, more preferably 0.5 or less, and even more preferably 0.3 or less, from the perspective of imparting excellent slipperiness to the thermally conductive molding and of improving workability in an application of the thermally conductive molding to an adherend. The lower limit of the kinetic coefficient of friction is not particularly limited but is, for example, 0.05 or more. In the present specification, the kinetic coefficient of friction is measured as a kinetic coefficient of friction with respect to SUS, based on a method in accordance with ISO8295:1995 (JISK7125:1999), and refers to a value measured under conditions of a load of 2200 g and a tensile speed of 100 mm/minute.

Preferable examples of the second layer (the film (B) including the second layer) used in the thermally conductive molding according to the present embodiment includes those including at least one type selected from the group consisting of polyester resins, nylon, PLA (polylactic acid) resins, ionomer resins, polyethylene resins, and polypropylene resins. Among these, from the perspectives of deep drawabilities, slipperiness, and releasability from the resin molding, it is preferable to use at least one type selected from the group consisting of high density polyethylene resins and polypropylene resins. When using a low density polyethylene or an ultra low density polyethylene resin, it is preferable to use a blend including a release resin such as silicone.

The thickness of the second layer (the film (B) including the second layer) may be set as appropriate in a range that does not significantly inhibit the effects of the present invention according to the application of the thermally conductive molding; and the type of the constituents of the second layer. The thickness of the second layer may be, for example, from 1 to 100 μm, from 3 to 50 μm, or from 5 to 20 μm. If the thickness of the second layer is within the range described above, strength of the molding can be sufficiently ensured, and moldability can be ensured while heat resistance can be suppressed.

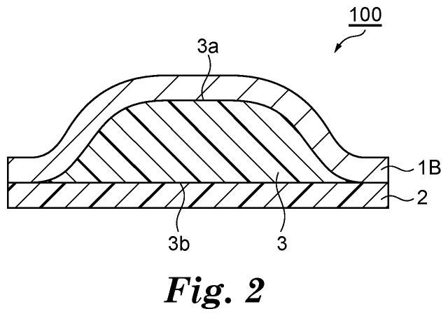

The thermally conductive molding according to the present embodiment may further include a second film disposed on a surface opposite to the first surface of the resin molding described above. FIG. 2 is a cross-sectional view illustrating one embodiment of a thermally conductive molding. As illustrated in FIG. 2, a thermally conductive molding 100 includes a second layer (film (B) including a second layer) 1B; a second film 2; and a resin molding 3, and the resin molding 3 having a first surface 3a with a three-dimensional shape, and a surface 3b opposite to the first surface. The second layer (the film (B) including the second layer) is disposed so as to conform to the three-dimensional shape of the first surface 3a of the resin molding 3, and the second film 2 is disposed on the surface 3b opposite to the first surface of the resin molding 3.

When the thermally conductive molding further includes the second film 2, the oxygen transmissivity of the second film 2 may be less than 1000 ml/m²·24 h·atm. Since the oxygen transmissivity of the second film 2 is less than 1000 ml/m²·24 h·atm, inhibition of radical polymerization by oxygen is more effectively prevented in the below-described production of thermally conductive molding through radical polymerization of an acrylic monomer to produce a (meth)acrylate polymer. From this perspective, the oxygen transmissivity of the second film 2 is preferably 200 ml/m²·24 h·atm or less, more preferably 150 ml/m²·24 h·atm or less, and even more preferably 100 ml/m²·24 h·atm or less. The lower limit of the oxygen transmissivity of the second film 2 is not particularly limited but may be, for example, 0.01 ml/m²·24 h·atm or more. In the present specification, “oxygen transmissivity” refers to the oxygen transmissivity measured using an oxygen transmission rate test system OX-TRAN, Model 2/21 manufactured by the MOCON Inc. In a case where the oxygen transmissivity is more than 200 ml/m²·24 h·atm, a portion of the test cell is masked in the measurement.

Examples of the second film include films containing at least one type selected from the group consisting of polyvinyl alcohol, ethylene-vinyl alcohol copolymers (EVOH), polyvinylidene fluoride (PVDF), and polyacrylonitrile, biaxially stretched polyethylene terephthalate (biaxially stretched PET), biaxially stretched polyethylene naphthalate (biaxially stretched PEN), unstretched nylon, and unstretched PET. Among these, from the perspective of releasability from the resin molding, releasability from the first film described below, and more sufficient suppression of oxygen transmissivity, the film preferably contains at least one type selected from the group consisting of biaxially stretched PET, biaxially stretched PEN, and unstretched nylon. As described below, when the thermally conductive molding is used after removing the second film, from the perspective of facilitating release, a release agent such as silicone may be applied to the second film on the surface to be in contact with the curable composition described below.

The thickness of the second film 2 may be set as appropriate in a range that does not significantly inhibit the effects of the present invention, depending on the application of the thermally conductive molding 100 and on the type of the film. The thickness of the second film 2 may be, for example, from 5 to 200 μm, from 10 to 100 μm, or from 20 to 75 μm.

Further, the second film may be composed of one layer, or two or more layers. When the second film is composed of two or more layers, at least one of the layers may have the characteristics of the second film according to the present embodiment described above, and all layers may have the characteristics of the second film according to the present embodiment. When the second film is composed of two or more layers, these layers may be laminated with an adhesive layer or the like interposed therebetween as appropriate.

Furthermore, the thermally conductive molding 100 may include a reinforcing substrate (not illustrated) such as a knitted fabric, a woven fabric, or a nonwoven fabric between the second film 2 and the resin molding 3 or in the resin molding 3. The inclusion of the reinforcing substrate suppresses stretchability of the thermally conductive molding 100 in a planar direction, suppresses the possibility of defects such as cracking when removing the thermally conductive molding from the mold, and thus improves handling ease. Among these, a non-woven fabric is preferable because it has excellent impregnating properties for the curable composition described below. The material of the reinforcing substrate may be glass, vinylon, aramid, nylon, polyolefin, polyester, or acrylic and is preferably glass because it can impart flame retardancy. The thickness of the reinforcing substrate may be, for example, 20 μm or more or 40 μm or more and, for example, may be 0.2 mm or less or 0.1 mm or less.

### Production Method for Thermally Conductive Molding

Next, a production method for the thermally conductive molding will be described. The production method for a thermally conductive molding according to the present embodiment includes: a step (first step) of providing a first film that is disposed on a mold having a three-dimensional shape so as to conform to the three-dimensional shape, that has a shape corresponding to the three-dimensional shape, and that has a first layer and a second layer that is releasably adhered to the first layer on the surface opposite to the mold of the first layer; a step (second step) of disposing a curable composition including a thermally conductive material and a (meth)acrylic monomer on the first film; a step (third step) of disposing a second film on the curable composition and sandwiching the curable composition between the first film and the second film; a step (fourth step) of radically polymerizing the (meth)acrylic monomer in the curable composition to form a cured product of the curable composition between the first film and the second film; and a step (fifth step) of releasing the first layer from the second layer to obtain a thermally conductive molding including the second layer, the cured product, and the second film.

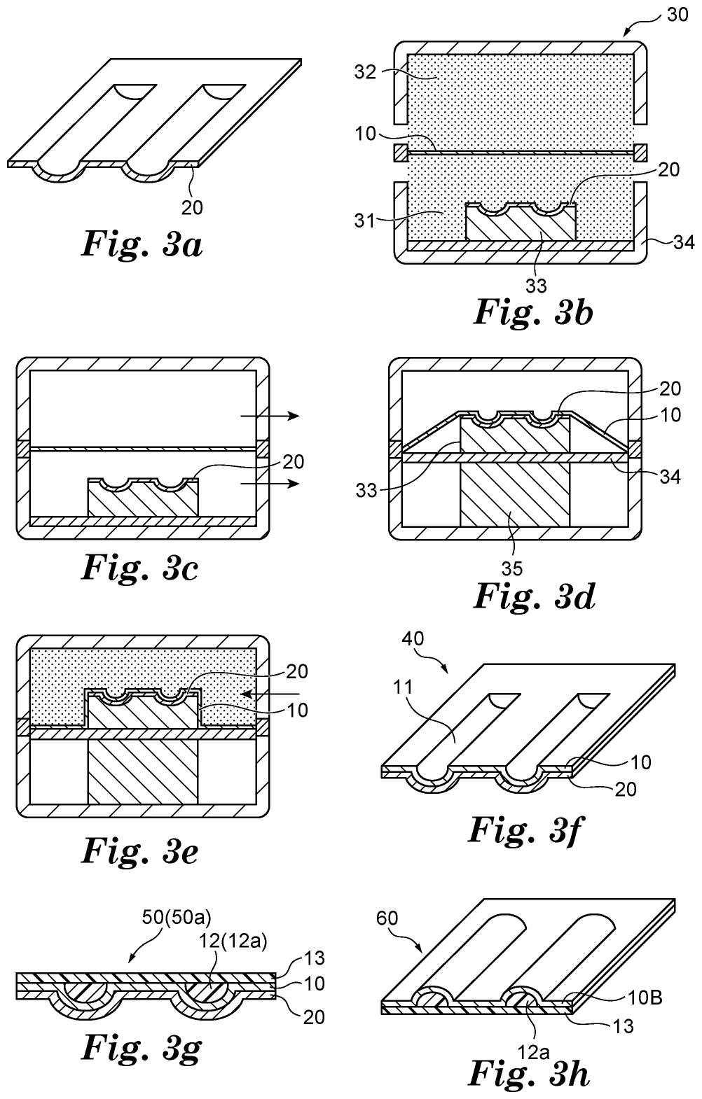

FIG. 3 is a process cross-sectional view illustrating an embodiment of a production method for a thermally conductive molding. The steps described above will be described below with reference to the drawings as appropriate.

### First Step

The first step is a step of preparing a first film that is disposed on a mold having a three-dimensional shape so as to conform to the three-dimensional shape, that has a shape corresponding to the three-dimensional shape, and that has a first layer and a second layer that is releasably adhered to the first layer on the surface opposite to the mold of the first layer. Examples of the method for preparing the first film having the three-dimensional shape corresponding to the mold include vacuum thermocompression bonding, vacuum molding, and film insert molding.

A specific method for vacuum thermocompression bonding will be described below as an example. First, a mold 20 having a predetermined three-dimensional shape as illustrated in FIG. 3(a) is prepared. As illustrated in FIG. 3(b), an exemplary vacuum thermocompression bonding apparatus 30 includes a first vacuum chamber 31 and a second vacuum chamber 32 above and below and includes a jig for setting a first film 10 to be affixed to the mold 20 between the upper and lower vacuum chambers. In addition, in the first vacuum chamber 31, a partition plate 34 and a pedestal 33 are disposed on an elevating table 35 (not illustrated) that can be moved up and down, and the mold 20 is set on the pedestal 33. The vacuum thermocompression bonding apparatus 30 may be a commercially available product such as a double-sided vacuum molding machine (manufactured by Fu-se Vacuum Forming Ltd.).

As illustrated in FIG. 3(b), first, the first film 10 is set between the upper and lower vacuum chambers with the first vacuum chamber 31 and the second vacuum chamber 32 of the vacuum thermocompression bonding apparatus 30 opened to atmospheric pressure. The mold 20 is set on the pedestal 33 in the first vacuum chamber 31. At this time, the first film 10 includes a first layer 10A and the second layer 10B. The first film 10 is a laminate 10 (multilayer film 10) of a film (A) including the first layer 10A and a film (B) including the second layer 10B that is releasably adhered to one surface of the film (A) and is set such that the first layer 10A and the mold 20 are opposite each other.

Next, as illustrated in FIG. 3(c), the first vacuum chamber 31 and the second vacuum chamber 32 are closed, depressurized, thereby creating a vacuum inside of these chambers. After or simultaneously with the creation of the vacuum, the first film 10 is then heated. Next, as illustrated in FIG. 3(d), the elevating table 35 is raised and the mold 20 is pushed up to the second vacuum chamber 32. The heating operation may be performed with, for example, a lamp heater (not illustrated) integrated into the ceiling of the second vacuum chamber 32. The heating temperature is not particularly limited but is normally 50° C. or higher or 130° C. or higher; and 180° C. or lower or 160° C. or lower. The vacuum level of the vacuum atmosphere may be, for example, 0.10 atm or less, 0.05 atm or less, or 0.01 atm or less, given that the atmospheric pressure is 1 atm.

The heated first film 10 is pressed against the surface of the mold 20 and is stretched. After or simultaneously with the stretching, as illustrated in FIG. 3(e), the inside of the second vacuum chamber 32 is pressurized to an appropriate pressure (e.g., from 1 atm to 3 atm). By the pressure differential, the heated first film 10 adheres to the exposed surface of the mold 20, stretches conforming to the three-dimensional shape of the exposed surface, and forms a coating that is releasably adhered to the surface of the mold 20. Alternatively, after the decompression and heating are performed in the state illustrated in FIG. 3(c), the inside of the second vacuum chamber 32 is pressurized so as to cover the exposed surface of the mold 20 with the first film 10.

Thereafter, the above and below first vacuum chamber 31 and second vacuum chamber 32 are opened to the atmospheric pressure again, and the mold 20 covered by the first film 10 is taken out. As illustrated in FIG. 3(f), an edge of the first film 10 that is in close contact with the surface of the mold 20 is trimmed, thus obtaining an integral product 40 including the first film 10 and the mold 20. A method for performing the second step and the third step using the integral product 40 is described below, but in the present embodiment, the second step may be performed using the first film 10 which has been molded into a three-dimensional shape by removing the mold 20 from the integral product 40, and the third step may be performed after removing the mold 20 following the second step, and the fourth step may be performed after removing the mold 20 following the third step.

In the production method for a thermally conductive molding according to the present embodiment, the oxygen transmissivity of the first film 10 needs to be less than 1.000 ml/m²·24 h·atm. When the oxygen transmissivity of the first film 10 is less than 1000 ml/m²·24 h·atm, inhibition of radical polymerization can be prevented in the production of a (meth)acrylate polymer through radical polymerization of a (meth)acrylic monomer. From this perspective, the oxygen transmissivity of the first film 10 is preferably 200 ml/m²·24 h·atm or less, more preferably 150 ml/m²·24 h·atm or less, and even more preferably 100 ml/m²·24 h·atm or less. The lower limit of oxygen transmissivity of the first film 10 is not particularly limited but is, for example, 0.01 ml/m²·24 h·atm or more.

Furthermore, the 50% elongation strength of the first film 10 at a temperature of 100° C. needs to be 100 N/25 mm or less. If the 50% elongation strength of the first film 10 at 100° C. is 100 N/25 mm or less, flexibility of the film can be sufficiently ensured, and good conformance to the mold can be maintained. From this perspective, the 50% elongation strength of the first film 10 at a temperature of 100° C. may be, for example, 50 N/25 mm or less or 25 N/25 mm or less. In the present specification, “50% elongation strength at 100° C.” refers to the elongation strength measured by a method in accordance with ISO527-3 (JISK7172:1999).

In the first film 10, the kinetic coefficient of friction of the second layer 10B on the first layer 10A side is preferably 0.7 or less, more preferably 0.5 or less, and even more preferably 0.3 or less, from the perspective of giving excellent slipperiness of the second layer 10B and of improving workability in assembling operations such as attaching, in an application to an adherend, the thermally conductive molding to a component and subsequently squeezing the component into a gap. The lower limit of the kinetic coefficient of friction of the second layer 10B is not particularly limited but is, for example, 0.05 or more.

Preferable examples of the first layer 10A that constitutes the first film 10 include the films containing at least one type selected from the group consisting of polyvinyl alcohol, ethylene-vinyl alcohol copolymers (EVOH), polyvinylidene fluoride (PVDF), polyacrylonitrile, unstretched nylon, and unstretched PET. Among these, from the perspective of low oxygen transmissivity, releasability with respect to the second layer 10B, deep drawability, slipperiness, and the like, the film preferably contains at least one type selected from the group consisting of EVOH, PVDF, and unstretched nylon.

The first layer 10A may be composed of one layer or two or more layers. When the first layer 10A is composed of two or more layers, at least one of the layers may have the characteristics of the first layer according to the present embodiment described above, and all layers may have the characteristics of the first layer according to the present embodiment described above. When the first layer 10A is composed of two or more layers, these layers may be laminated with an adhesive layer (e.g., a layer containing maleic anhydride modified polyethylene or acid modified EVA) or the like interposed therebetween as appropriate.

Preferred examples of the second layer 10B constituting the first film 10 include those containing at least one type selected from the group consisting of polyester resins, nylon, PLA resins, ionomer resins, polyethylene resins, and polypropylene resins. Among these, from the perspective of releasability from the first layer 10A, deep drawability, and slipperiness, the second layer 10B preferably contains at least one type selected from the group consisting of high density polyethylene resins and polypropylene resins. When it includes a low density polyethylene or an ultra low density polyethylene resin, the resin is preferably blended with a release resin such as silicone.

The second layer 10B may be composed of one layer, or two or more layers. In a case where the second layer 10B is composed of two or more layers, at least one of the layers may have the characteristics of the second layer according to the present embodiment described above, and all layers may have the characteristics of the second layer according to the present embodiment. In a case where the second 10B is composed of two or more layers, these layers may be laminated with an adhesive layer or the like interposed therebetween as appropriate.

The combination of the first layer 10A and the second layer 10B constituting the first film 10 is not particularly limited as long as the first layer 10A and the second layer 10B are releasably bonded, but the combination of the layer of the first layer 10A to be in contact with the second layer 10B and the layer of the second layer 10B to be in contact with the first layer 10A is preferably EVOH (or a resin containing EVOH) and polyethylene. The polyethylene preferably contains a release agent from the perspective of imparting particularly favorable slipperiness.

The thickness of the first film 10 may be set as appropriate in a range that does not significantly inhibit the effects of the present invention, depending on the application of the thermally conductive molding and on the type of the film. The thickness of the first film 10 may be, for example, from 3 to 200 μm, from 5 to 150 μm, or from 10 to 130 μm. If the thickness of the first film is within the range described above, the strength can be more sufficiently ensured while the oxygen transmissivity is more effectively suppressed, and moldability can be ensured while heat resistance can be suppressed.

The thickness of the film (A) including the first layer 10A in the first film may be set as appropriate in a range that does not significantly inhibit the effects of the present invention, according to the application of the thermally conductive molding; and the type of the film. The thickness of the film (A) may be, for example, from 30 to 200 μm, from 40 to 150 μm, or from 50 to 130 μm. If the thickness of the film (A) is within the range described above, strength can be more sufficiently ensured while oxygen transmissivity is more effectively suppressed, and moldability can be ensured.

The thickness of the film (B) including the second layer 10B in the first film may be set as appropriate in a range that does not significantly inhibit the effects of the present invention, according to the application of the thermally conductive molding; and the type of the film. The thickness of the film (B) may be, for example, from 1 to 100 μm, from 3 to 50 μm, or from 5 to 20 μm. If the thickness of the film (B) is within the range described above, strength of the molding can be sufficiently ensured, and moldability can be ensured while heat resistance can be suppressed.

From the perspective described above, the ratio of a thickness T_{A} of the film (A) to a thickness T_{B} of the film (B) (T_{B}/T_{A}) is preferably from 0.01 to 1.00, more preferably from 0.02 to 0.5, and even more preferably from 0.05 to 0.3.

The oxygen transmissivity of the film (A) including the first layer 10A in the first film is preferably less than 1000 ml/m²·24 h·atm. Due to the oxygen transmissivity of the film (A) being less than 1000 ml/m²·24 h·atm, inhibition of radical polymerization by oxygen is suppressed in the production of a (meth)acrylic monomer through radical polymerization of a (meth)acrylate polymer. From this perspective, the oxygen transmissivity of the film (A) is preferably 200 ml/m²·24 h·atm or less, more preferably 150 ml/m²·24 h·atm or less, and even more preferably 100 ml/m²·24 h·atm or less. The lower limit of oxygen transmissivity of the film (A) is not particularly limited but is, for example, 0.01 ml/m²·24 h·atm.

### Second Step

The second step is a step of disposing a curable composition containing a thermally conductive material and a (meth)acrylic monomer on the first film. An example of the second step is described below using FIG. 3.

A cavity 11 of the integral product 40 in FIG. 3(f) is filled with a curable composition containing a thermally conductive material and a (meth)acrylic monomer, and flattering treatment is performed as necessary using a blade or the like, thus forming a filling portion 12 to dispose the curable composition. The filling of the curable composition is not particularly limited, but it is preferable to apply a degassed product to prevent air contamination.

### Third Step

The third step is a step of disposing the second film on the curable composition and sandwiching the curable composition between the first film and the second film.

FIG. 3(g) illustrates a configuration in which a second film 13 is further applied to the filling portion 12 formed in the step described above. In this embodiment, the second film 13 can be disposed so as to cover the first film 10 and the filling portion 12 to obtain an integral product 50. In the third step, in a case where a reinforcing substrate such as a nonwoven fabric is disposed between the filling portion 12 and the second film 13, for example, the reinforcing substrate may be disposed on the second film 13 such that the reinforcing substrate and the filling portion 12 are in contact with each other. Alternatively, in a case where the reinforcing substrate is disposed in the filling portion 12, the curable composition may be impregnated with the reinforcing substrate in advance.

### Fourth Step

The fourth step is a step of radical polymerizing the (meth)acrylic monomer in the curable composition to form a cured product (resin molding) 12a of the curable composition between the first film 10 and the second film 13. As necessary, the mold 20 may be released from the first film 10 after formation of the cured product (resin molding) 12a of the curable composition. As a result, obtained is a structure 50a having a cured product (resin molding) 12a of the curable composition containing a thermally conductive material and a (meth)acrylate polymer.

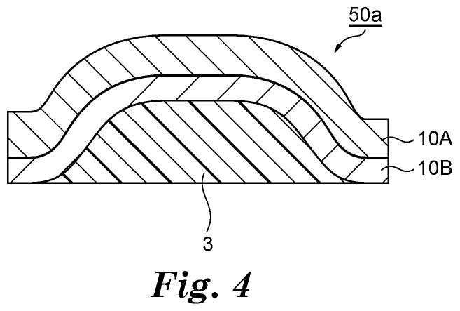

FIG. 4 is a cross-sectional view illustrating an embodiment of the structure. Through the fourth step, as illustrated in FIG. 4, obtained is the structure 50a that includes at least a resin molding 3 having a first surface with a three-dimensional shape; and a first film 10 being disposed on the first surface of the resin molding 3 so as to conform to the three-dimensional shape and including the second layer 10B and the first layer 10A that is releasably adhered to the second layer 10B on the surface opposite to the resin molding 3. The structure 50a may further include the second film 13 on a surface opposite to the first surface of the resin molding 3.

Radical polymerization can be performed by, for example, UV polymerization, electron beam polymerization, gamma irradiation polymerization, or ionizing beam irradiation. The UV light polymerization can be performed, for example, after forming the filling portion 12 by filling the cavity 11 with a curable composition containing an appropriate amount of a photopolymerization initiator, followed by UV irradiation. When polymerization is performed by particle energy beam polymerization such as electron beam polymerization, typically, no polymerization initiator is required.

Examples of the photopolymerization initiator include benzoin ethers such as benzoin ethyl ether and benzoin isopropyl ether; substituted acetophenones such as anisoin ethyl ether, anisoin isopropyl ether, Michler's ketone (4,4′-tetramethyldiaminobenzophenone), 2,2-dimethoxy-2-phenylacetophenone (e.g., trade name: KB-1 (made by Sartomer) and trade name: Irgacure 651 (manufactured by Ciba Specialty Chemicals Inc.)), and 2,2-dietoxyacetophenone; substituted®-ketols such as 2-methyl-2-hydroxypropiophenone; aromatic sulfonyl chlorides such as 2-naphthalenesulfonyl chloride; photoactive oxime compounds such as 1-phenone-1,1-propanedione-2-(o-ethoxycarbonyl)oxime; and acylphosphine oxide compounds such as bis(2,4,6-trimethylbenzoyl)-2,4,4-trimethyl-pentylphosphine oxide and 2,4,6-trimethylbenzoyl-diphenyl-phosphinoxide. The photopolymerization initiator may be used alone or in combination of two or more types thereof.

The content of the photopolymerization initiator included in the curable composition is not particularly limited but is normally from 0.05 to 2.0 parts by mass, per 100 parts by mass of the monomer component such as the (meth)acrylic monomer described above.

### Fifth Step

The fifth step is a step of releasing the first layer 10A from the second layer 10B to obtain a thermally conductive molding 60 including the second layer 10B, the cured product 12a, and the second film 13 as illustrated in FIG. 3(h). When the first layer 10A and the second layer 10B are released from each other, the structure 50a obtained via the fourth step may be optionally cooled.

The obtained thermally conductive molding may remove the second layer 10B and the second film 13 as necessary and may be punched out into pieces with appropriate sizes, thus obtaining thermally conductive moldings having different three-dimensional shapes. In a case where the thermally conductive molding is used as a product without removing the second layer 10B, there is an advantage that the second layer 10B improves slipperiness on its surface or the strength of the product when the molding is pressed into a gap in a battery or the like.

The thermally conductive molding obtained by the production method according to the present embodiment is used in vehicles, lithium-ion batteries (e.g., lithium-ion battery packs for automobiles), home appliances, and computer apparatuses. For example, it can be used as a heat dissipating member that is disposed to fill a space between a heat-generating component such as an IC chip and a heat-dissipating component such as a heat sink or a heat pipe so that the heat generated from the heat-generating component is efficiently transferred to the heat-dissipating component. In particular, the thermally conductive molding according to the present embodiment can be freely designed in its shape and size thus can be used, for example, as a substitute for a potting material of a circuit board and can also be used for heat-generating components having a complex shape such as a coil.

### EXAMPLES

The present invention will be described more specifically below using examples, but the present invention is not intended to be limited to the examples.

The abbreviations and details of each of the components used in the examples are described below.

### Preparation of Curable Compositions

The components listed in table 1 were charged into a planetary mixer at the mixing proportion (mass ratio) shown in Table 1 and kneaded under a reduced pressure (0.01 MPa) for 30 minutes for deaeration and mixing, thus obtaining a curable composition. In the curable composition described below, the volume ratio of the thermally conductive filler was 67.0% by volume.

TABLE 1

| | | Curable |
|---|---|---|
| | | compositions |
| (Meth)acrylic monomer | LA | 50 |
| | ISTA | 50 |
| | HDDA | 0.2 |
| Photopolymerization initiator | IRGACURE 819 | 0.1 |
| Plasticizer | T10 | 25 |
| Antioxidant | IRGAN0X1010 | 1.5 |
| | A0503 | 4.0 |
| Thermally conductive filler | B53 | 452 |
| | BF083 | 224 |
| Dispersant | BYK-145 | 4.0 |

Each of the abbreviations shown in Table 1 has the following meaning.
((Meth)acrylic monomer)
LA: Lauryl acrylate
ISTA Isostearyl acrylate
HDDA: 1,6-hexanediol diacrylate (Photopolymerization initiator)
IRGACURE 819: bis(2,4,6-trimethylbenzoyl)-phenylphosphine oxide, manufactured by BASF (Plasticizer)
T10: trimellitate plasticizer, Trimex T-10, manufactured by Kao Corporation (Antioxidant)
IRGANOX 1010: pentaerythritol tetrakis(3-(3,5-di-tert-butyl-4-hydroxyphenyl)propionate), manufactured by BASF
O503: ADEKA STAB AO503, ditridecyl thiodipropionate, manufactured by ADEKA Corporation (Thermally conductive filler)
B53: aluminum hydroxide (average particle size: 50 μm), made by Nippon Light Metal Company, Ltd.
BF083: aluminum hydroxide (average particle size: 8 μm), manufactured by
Nippon Light Metal Company, Ltd. (Dispersant)
BYK-145: wet dispersant DISPERBYK-145, manufactured by BYK-Chemie Japan.

### Making of First Film

### Film A

An ionomer resin (trade name: Himilanl 554, a zinc ionomer of an ethylene methacrylic acid copolymer, manufactured by Dow-Mitsui Polychemicals Company, Ltd.), a polyethylene (PE) resin (product name: ADMER NF518, a modified copolymerized polyethylene, manufactured by Mitsui Chemicals, Inc.), and an EVOH resin (trade name: EVAL SP482B, an ethylene-vinyl alcohol copolymer, manufactured by Kuraray Co., Ltd.) were used as the resin materials composing the first layer, an ionomer resin (trade name: Himilan 1554, a zinc ionomer of an ethylene methacrylic acid copolymer, manufactured by Mitsui-DuPont Polychemical Co., Ltd.) was used as the resin material composing the second layer, and these resin materials were extruded using a co-extruder (model: LF-400, manufactured by LabTech Engineering Company, Ltd.), thus making a first film A (thickness: T_{A}+T_{B}: 86 μm) including a first layer including an ionomer layer, a PE layer, and an EVOH layer laminated in this order (thickness: T_{A}: 80 μm) and a second layer including an ionomer layer (thickness T_{B}: 6 μm). The oxygen transmissivity of the film A was 1.0 ml/m²·24 hr atm, the 50% elongation strength at 100° C. was 2.9 N/25 mm, and the kinetic coefficient of friction of the surface of the second layer on the first layer side was 0.248.

### Film B

The same procedure for the first film A described above was performed, except that a polypropylene (PP) resin (product name: Wintec WFX4, a metallocene polypropylene, manufactured by Japan Polypropylene Corporation) was used as the resin material composing the second layer, thus making a first film B (thickness: T_{A}+T_{B}: 116 μm) including a first layer including an ionomer layer, a PE layer, and an EVOH layer laminated in this order (thickness: T_{A}: 108 μm) and a second layer including a PP layer (thickness T_{B}: 8 μm). The oxygen transmissivity of the film B was 0.4 ml/m²·24 h·atm, the 50% elongation strength at 100° C. was 3.5 N/25 mm, and the kinetic coefficient of friction of the surface of the second layer on the first layer side was 0.224.

### Film C

The same procedure for the first film A described above was performed, except that an ionomer resin (trade name: Himilan 1601, a zinc ionomer of an ethylene methacrylic acid copolymer, manufactured by Dow-Mitsui Polychemicals Company, Ltd.), a high density polyethylene (HDPE) resin (trade name: MODIC H503, manufactured by Mitsubishi Chemical Corporation), and an EVOH resin (trade name: EVAL SP482B, an ethylene-vinyl alcohol copolymer, manufactured by Kuraray Co., Ltd.) were used as the resin materials composing the first layer, and a mixture of a polyethylene (PE) resin (trade name: HARMOREX NF384A, a gas phase metallocene polyethylene, manufactured by Japan Polyethylene Corporation) and a silicone compound (trade name: EY-27-202H, Dow Corning Toray Co., Ltd.) (mixing ratio (mass ratio): 100/1) was used as the resin materials composing the second layer, thus making a first film C (thickness: T_{A}+T_{B}: 108 μm) including a first layer including an ionomer layer, a HDPE layer, and an EVOH layer laminated in this order (thickness: T_{A}: 85 μm) and a second layer including a PE resin and a silicone compound (thickness T_{B}: 23 μm). The oxygen transmissivity of the film C was 1.0 ml/m²·24 h·atm, the 50% elongation strength at 100° C. was 4.7 N/25 mm, and the kinetic coefficient of friction of the surface of the second layer on the first layer side was 0.293.

Film D The same operation for the first film C described above was performed, thus making a first film D (thickness: T_{A}+T_{B}: 88 μm) including a first layer (thickness T_{A}: 78 μm) including an ionomer layer, an HDFE layer, and an EVOH layer laminated in this order, and a second layer (thickness T_{B}: 10 μm) including a PE resin and a silicone compound. The oxygen transmissivity of the film D was 1.0 ml/m²·24 h·atm, the 50% elongation strength at 100° C. was 3.1 N/25 mm, and the kinetic coefficient of friction of the surface of the second layer on the first layer side was 0.281.

### Film E

The same procedure for the first film C described above was performed, except that the mixing ratio of the polyethylene resin and the silicone compound was changed to 98/2 for the resin material composing the second layer, thus making a first film E (thickness: T_{A}+T_{B}: 90 Mm) including a first layer including an ionomer layer, an HDPE layer, and an EVOH layer laminated in this order (thickness: T_{A}: 73 μm) and a second layer including a PE resin and a silicone compound (thickness T_{B}: 17 μm). The oxygen transmissivity of the film E was 0.8 ml/m²·24 h·atm, the 50% elongation strength at 100° C. was 3.3 N/25 mm, and the kinetic coefficient of friction of the surface of the second layer on the first layer side was 0.217.

### Film F

An ionomer resin (trade name: Himilan 1554, a zinc ionomer of an ethylene-methacrylic acid copolymer, manufactured by Dow-Mitsui Polychemicals Company, Ltd.) was used as the resin material and extruded using an extruder, thus making a film F (thickness: 6 μm) including an ionomer layer. The kinetic coefficient of friction of the film F was 0.217. The oxygen transmissivity of the film F was not less than the measurement limit (2000 ml/m²·24 h·atm).

### Film G

A polypropylene resin (trade name: Wintec WFX4, metallocene polypropylene, manufactured by Japan Polypropylene Corporation) was used as the resin material and extruded using an extruder, thus making a film G (thickness: 8 μm) including a PP layer. The kinetic coefficient of friction of the film G was 0.217. The oxygen transmissivity of the film g was not less than the measurement limit (2000 ml/m²·24 h·atm).

### Film H

A mixture of a polyethylene (PE) resin (trade name: HARMOREX NF384A, a gas phase metallocene polyethylene, manufactured by Japan Polyethylene Corporation) and a silicone compound (trade name: EY27-202H, manufactured by Dow Corning Toray Co., Ltd.) (mixing ratio (mass ratio): 100/1) was used as the resin material and extruded with an extruder, thus making a film H (thickness: 23 μm) including a PE resin and a silicone compound. The kinetic coefficient of friction of the film H was 0.217. The oxygen transmissivity of the film H was not less than the measurement limit (2000 ml/m²·24 h·atm).

### Film I

A film I (thickness: 10 μm) composed of a PE resin and a silicone compound was made in the same manner as for the film H. The kinetic coefficient of friction of the film I was 0.217. The oxygen transmissivity of the film I was not less than the measurement limit (2000 ml/m²·24 h·atm).

### Film J

A film J (thickness: 17 μm) composed of a PE resin and a silicone compound was made in the same manner as for the film H, except that the mixing ration of the polyethylene resin and the silicone compound in the resin material was changed to 98/2. The kinetic coefficient of friction of the film J was 0.217. The oxygen transmissivity of the film J was not less than the measurement limit (2000 ml/m²·24 hr·atm).

### Making of Thermally Conductive Molding

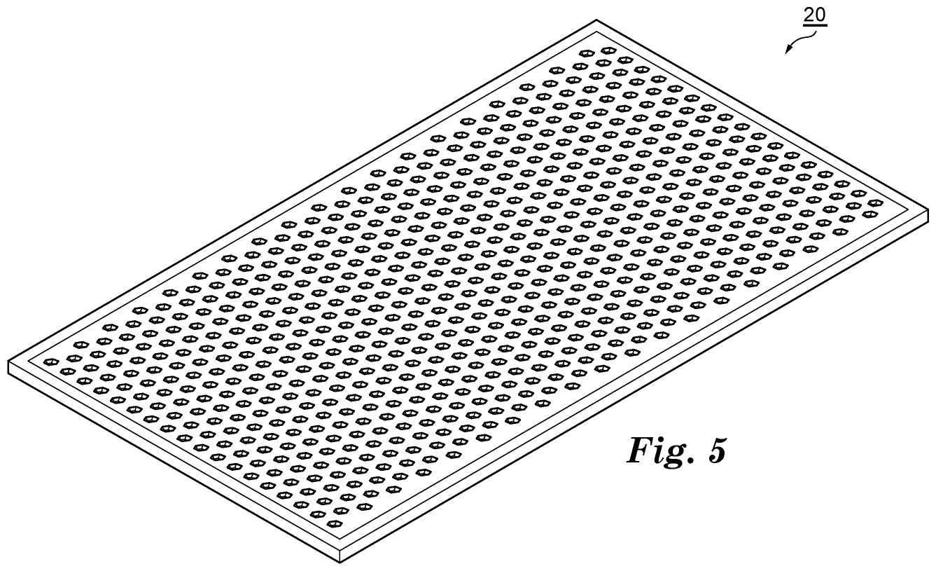

As illustrated in FIG. 3(b), the films A to J made as described above were fixed on the resin mold 20 placed in a double-sided vacuum molding machine (manufactured by Fu-se Vacuum Forming Ltd.) used as the vacuum thermocompression bonding apparatus 30 such that the first layer and the mold were opposite each other. Heating conditions were set such that the surface temperature of the film was 120° C., and the heated film was laminated on the surface of the mold 20 so that air was not entrained in accordance with the procedure as illustrated in FIGS. 3(c) to 3(e) described above, and the integral product 40 as illustrated in FIG. 3(f) was made. Here, as illustrated in FIG. 5, the mold 20 was made and used, with a 3D printer so as to have a shape to obtain a three-dimensional shape in which a plurality of substantially hexagonal pyramidal three-dimensional portions are regularly arranged in a lattice.

The cavity 11 of the integral product 40 was filled with the curable composition obtained above, and then the second film 13 (polyester film liner, manufactured by Teijin Film Solutions Limited, trade name “Purex A50”, thickness: 50 μm, oxygen transmissivity: 16) was laminated onto the filled curable composition. A rubber roller was applied on the second film 13 so that the second film 13 was uniformly adhered to the mold 20, thus making the integral product 50. Using a black light lamp, the integral product 50 was irradiated with UV for 15 minutes from the second film 13 side at a distance of 5.5 cm to polymerize the acrylic monomer contained in the curable composition (irradiation conditions: UV-A (wavelength: from 315 to 380 nm), 7.46 mW/cm²), thus obtaining a structure. Next, the first layer and the second layer of the obtained structure were released from each other, thus making the thermally conductive molding 60 including the second layer (film (B)), the resin molding, and the second film in this order.

### Evaluation of Deep Drawability in Production of Thermally Conductive Molding

In the making of the thermally conductive molding described above, the presence or absence of tearing of the first film; and the presence or absence of adhesion of the first film to the base corner of the mold were visually confirmed, and deep drawability was evaluated in accordance with the following criteria. The results are shown in Tables 2 and 3.

A: No film tearing or wrinkling was observed, and no floating was observed in the bottom corner of the mold.

B: Film tearing and wrinkling were observed, and floating was observed at the bottom corner of the mold.

### Cured State of Thermally Conductive Molding

The second layer (film (B)) was released from the obtained thermally conductive molding 60, and the cured state of the curable composition was confirmed visually and by a finger touch. The cured state of the curable composition was evaluated according to the following criteria. The results are shown in Tables 2 and 3.

A: The film remained transparent, the presence of tackiness was confirmed by a finger touch, and thus prevention of polymerization inhibition was confirmed.

B: The curable composition in an uncured state slightly remained and became cloudy on the top of the thermally conductive molding and the film surface, and thus occurrence of polymerization inhibition was confirmed.

### Evaluation of Thermal Resistance Value and Thermal Conductivity

The thermal resistance value and thermal conductivity of the samples of the thermally conductive molding 60 obtained from the films A to E were measured using TIM Tester (manufactured by Analysis Tech, Inc.) in accordance with ASTMD 5470. First, a cooling plate, which includes a heater, a load cell, and a cylinder on the top, and a cylindrical insulating material set on the outside of the cylinder so that it can move to the bottom, was provided, and a sample with a diameter of 33 mm was placed on the cooling plate. The cylinder was lowered and pressurized to 100 kPa, the thermal resistance value Rt was calculated from the temperature difference between the temperature T1 of the heater and the temperature T2 of the cooling plate by the following formula, and the thermal conductivity was calculated from the thermal resistance value Rt and the thickness of the sample. The calculation results are shown in Table 4.

Rt=[(T1−T2)/Q]×S

Rt: thermal resistance value

T1: heater temperature (° C.)

T2: cooling plate temperature (° C.)

Q: applied power (W)

S: sample contact area (cm²)

TABLE 2

| | Example | Example | Example | Example | Example |
|---|---|---|---|---|---|
| | 1 | 2 | 3 | 4 | 5 |
| First Film | Film A | Film B | Film C | Film D | Film E |
| Deep | A | A | A | A | A |
| drawability | | | | | |
| Cured state | A | A | A | A | A |

TABLE 3

| | Compar- | Compar- | Compar- | Compar- | Compar- |
|---|---|---|---|---|---|
| | ative | ative | ative | ative | ative |
| | Example 1 | Example 3 | Example 4 | Example 5 | Example 7 |
| Film | Film F | Film G | Film H | Film I | Film J |
| Deep | B | B | B | B | B |
| draw- | | | | | |
| ability | | | | | |
| Cured | B | B | B | B | B |
| state | | | | | |

TABLE 4

| | Example | Example | Example | Example | Example |
|---|---|---|---|---|---|
| | 1 | 2 | 3 | 4 | 5 |
| First Film | Film A | Film B | Film C | Film D | Film E |
| Thermal | 14.0 | 14.2 | 14.6 | 14.2 | 14.4 |
| resistance | | | | | |
| value | | | | | |
| Thermal | 2.04 | 1.93 | 1.91 | 1.95 | 1.96 |
| conductivity | | | | | |

### REFERENCE SIGNS LIST

1B second layer,
2 5 second film,
3 resin molding,
3a first surface,
3b surface opposite to the first surface,
10 first film (laminate, multilayer film),
10A 10 first layer,
10B second layer,
12a resin molding,
13 second film,
50a structure,
15 thermally conductive molding,
100 thermally conductive molding.

1. A production method for a thermally conductive molding, the production method comprising:
a step of preparing a first film that is disposed on a mold having a three-dimensional shape so as to conform to the three-dimensional shape, that has a shape corresponding to the three-dimensional shape, and that has a first layer and a second layer that is releasably adhered to the first layer on a surface opposite to the mold of the first layer;
a step of disposing a curable composition including a thermally conductive material and a (meth)acrylic monomer on the first film;
a step of disposing a second film on the curable composition and sandwiching the curable composition between the first film and the second film;
a step of radically polymerizing the (meth)acrylic monomer in the curable composition to form a cured product of the curable composition between the first film and the second film; and
a step of releasing the first layer from the second layer to obtain a thermally conductive molding including the second layer, the cured product, and the second film,
wherein an oxygen transmissivity of the first film is less than 1000 ml/m²·24 h·atm, and a 50% elongation strength of the first film at 100° C. is 100 N/25 mm or less.

2. The production method for the thermally conductive molding according to claim 1, wherein in the thermally conductive molding, the kinetic coefficient of friction of a surface of the second layer opposite to the cured product is 0.7 or less.

3. The production method for the thermally conductive molding according to claim 1, wherein the first film is a laminate of a film (A) including the first layer and a film (B) including the second layer, and the ratio (T_{B}/T_{A}) between a thickness of the film (A) (T_{A}) and the thickness of the film (B) (T_{B}) is from 0.01 to 1.00.

4. The production method for the thermally conductive molding according to claim 3, wherein an oxygen transmissivity of the film (A) is less than 1000 ml/m²·24 h·atm.

5. A structure comprising:
the thermally conductive molding according to claim 11,
wherein the first film has a second layer and a first layer that is releasably adhered to a surface of the second layer opposite to the resin molding, an oxygen transmissivity of the first film is less than 1000 ml/m²·24 h·atm, and a 50% elongation strength of the first film at 100° C. is 100 N/25 mm or less.

6. The structure according to claim 5, the structure further comprising a second film disposed on a surface opposite to the first surface of the resin molding.

7. The structure according to claim 5, wherein the kinetic coefficient of friction of a surface of the second layer on the opposite side to the resin molding is 0.7 or less.

8. The structure according to claim 5, wherein the first film is a laminate of a film (A) including the first layer and a film (B) including the second layer, and the ratio (T_{B}/T_{A}) between a thickness of the film (A) (T_{A}) and the thickness of the film (B) (T_{B}) is from 0.01 to 1.00.

9. The structure according to claim 8, wherein an oxygen transmissivity of the film (A) is less than 1000 ml/m²·24 h·atm.

10. A thermally conductive molding being formed by releasing the first layer from the second layer of the structure according to claim 5, and comprising the second layer and the resin molding.

11. A thermally conductive molding comprising:
a resin molding having a first surface with a three-dimensional shape and including a thermally conductive material and a (meth)acrylate polymer; and
a film disposed on the first surface of the resin molding so as to conform to the three-dimensional shape.

12. The thermally conductive molding according to claim 11, wherein the kinetic coefficient of friction of a surface of the film opposite to the resin molding is 0.7 or less.

13. The thermally conductive molding according to claim 11, further comprising a second film disposed on a surface opposite to the first surface of the resin molding.

14. A multilayer film comprising a first layer having an oxygen transmissivity of less than 1000 ml/m²·24 h·atm and a second layer that is releasably adhered to one surface of the first layer, wherein the kinetic coefficient of friction of a surface of the second layer on the first layer side is 0.7 or less.

15. The production method for the thermally conductive molding according to claim 2, wherein the first film is a laminate of a film (A) including the first layer and a film (B) including the second layer, the ratio (T_{B}/T_{A}) between a thickness of the film (A) (T_{A}) and the thickness of the film (B) (T_{B}) is from 0.01 to 1.00, and an oxygen transmissivity of the film (A) is less than 1000 ml/m²·24 h·atm.

16. The structure according to claim 6, wherein the kinetic coefficient of friction of a surface of the second layer on the opposite side to the resin molding is 0.7 or less.

17. The structure according to claim 16, wherein the first film is a laminate of a film (A) including the first layer and a film (B) including the second layer, and the ratio (T_{B}/T_{A}) between a thickness of the film (A) (T_{A}) and the thickness of the film (B) (T_{B}) is from 0.01 to 1.00.

18. The structure according to claim 17, wherein an oxygen transmissivity of the film (A) is less than 1000 ml/m²·24 h·atm.

19. A thermally conductive molding being formed by releasing the first layer from the second layer of the structure according to claim 18, and comprising the second layer and the resin molding.

20. The thermally conductive molding according to claim 12, further comprising a second film disposed on a surface opposite to the first surface of the resin molding.
